(19) United States
(12) Patent Application Publication
(10) Pub. No.: US 2023/0093008 A1
(43) Pub. Date: Mar. 23, 2023

(54) MICROELECTRONIC PACKAGE WITH DIELECTRIC LAYER INCLUDING SELF-ASSEMBLED FILLER-DEPLETED REGIONS

(71) Applicant: Intel Corporation, Santa Clara, CA (US)

(72) Inventors: Brandon C. MARIN, Gilbert, AZ (US); Aleksandar ALEKSOV, Chandler, AZ (US); Jeremy D. ECTON, Gilbert, AZ (US)

(21) Appl. No.: 17/482,092

(22) Filed: Sep. 22, 2021

(51) Int. Cl. H01L 23/498; H01L 21/48

(52) U.S. Cl. CPC H01L 23/49894; H01L 23/49838; H01L 21/4846; H01L 23/49822

(57) ABSTRACT

Techniques for self-assembly of regions in a dielectric layer with different electrical properties are described herein. In one example, a package includes a substrate, a layer of dielectric material over the substrate, the layer of dielectric material including a filler material. The package includes a plurality of conductive traces in the layer of dielectric material, and a filler-depleted radial region of the dielectric material around each of the plurality of conductive traces. The filler-depleted radial region has a lower volume-percentage of filler than other regions of the layer of dielectric material. In one example, the conductive traces, filler, or both include a coating to cause the filler and traces to have opposing surface chemistry.

### FIELD

The descriptions are generally related to semiconductor devices, and in specific examples, packages with a dielectric layer including self-assembled regions with different electrical properties.

### BACKGROUND

In server applications, power loss in the package substrate is becoming ever more critical, particularly for long signal routing lines. Insertion loss (which includes conductor loss and dielectric loss) can be a significant source of power loss in the system. Low loss tangent dielectric material may reduce dielectric losses. Conductor losses may be reduced by increasing the width of the trace. However, in order to maintain proper impedance matching, the dielectric material thickness above and below the traces is typically increased for wider traces (assuming there is no change in the dielectric constant.

The increase in dielectric thickness results in several challenges for substrate manufacturing. For example, it is more difficult to form vias in thicker dielectrics. Additionally, copper plating uniformity becomes problematic when skip layer techniques are used to increase the dielectric thicknesses above and below traces. Skip layer architectures may also result in CTV (chip area thickness variation) and/or BTV (bump top variation) control issues as well as lamination undulation.

Currently used dielectric materials in server substrate applications are buildup films that have a high filler content to enable low loss tangent and provide improved coefficient of thermal expansion (CTE) matching. However, the fillers (e.g., SiO₂) tend to have relatively high dielectric constants (e.g., around 4.0), which limits the possible reductions in the dielectric constant of the overall material. Furthermore, it is challenging to produce a low-K dielectric material while maintaining other desired properties (e.g., mechanical properties, thermal properties, etc.) of currently used dielectric materials. As such, it is not currently practical to replace an entire layer of a package substrate with a low loss tangent, low dielectric constant material.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing at least one implementation of the invention that includes one or more particular features, structures, or characteristics. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 illustrates an example of a cross-section of a portion of a package with a dielectric layer including a radial filler-depleted region.

FIG. 2 is a graph illustrating an example of the dielectric constant as a function of frequency within and external to a filler-depleted region of a dielectric material.

FIGS. 3A-3D illustrate examples of cross-sections of filler-depleted areas in a dielectric material.

FIG. 4 is a graph illustrating an example of filler density as a function of distance from the traces.

FIG. 5 is a flow diagram of an example of a process for the manufacture of a package with a dielectric layer having a low-filler region.

FIGS. 6A-6E illustrate cross-sectional views of various stages in the process of FIG. 5, according to one example.

FIG. 7 is a cross-sectional illustration of an example of an electronic assembly.

FIG. 8 provides an exemplary depiction of a computing system that may include one or more packages in accordance with the packages described herein.

Descriptions of certain details and implementations follow, including a description of the figures, which may depict some or all of the embodiments described below, as well as discussing other potential embodiments or implementations of the inventive concepts presented herein.

### DETAILED DESCRIPTION

Techniques for self-assembly of regions in a dielectric layer with different electrical properties are described herein.

Microelectronic packages typically include layers of a dielectric material, such as a build-up material. The build-up material surrounds traces in the package and provides structure in addition to insulation between adjacent traces. One typical build-up film is an epoxy-based composite material with a filler, such as a silica filler. The epoxy typically has a low dielectric constant but a high CTE. Filler is typically added to lower the CTE and prevent stress from thermal expansion that can cause the part to crack and fail. However, commonly used fillers have a high dielectric constant, which increases the overall dielectric constant of the build-up material.

The high dielectric constant due to the filler can cause capacitance to build up between traces, especially between closely spaced traces operating at high frequencies (e.g., differential traces such as for PCIe, UPI, or other high-speed routing), resulting in power loss. Reducing the filler would decrease the dielectric constant and reduce the capacitance buildup; however, reducing the filler in the dielectric material can cause the CTE to increase, increasing the likelihood of mechanical stress and part failure.

In one example, the surface chemistry of fillers within the dielectric buildup material, traces, or both, is tuned to drive self-assembly of low-dielectric constant regions within the dielectric material. The resulting structure can enable selective formation of low dielectric constant patches for better electrical performance without the need for homogeneous material property changes.

In one example, the fillers can be coated with a film that is hydrophilic and the traces can be coated in a hydrophobic material. The material is then heated, which causes the fillers to become mobile and move away from the traces of interest due to the different surface chemistry of the fillers and traces. Thus, in one example, a radial region that is depleted of filler is formed around the traces, resulting in a low-K area around the traces without negatively impacting the loss tangent and CTE of the other areas of the dielectric layer.

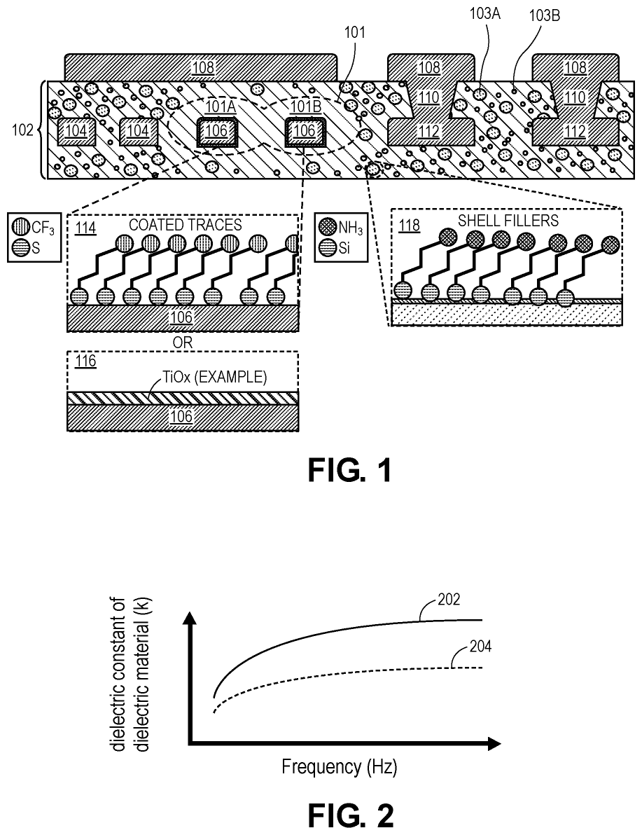

FIG. 1 illustrates an example of a cross-section of a portion of a package with a dielectric layer including a filler-depleted radial region.

The package of FIG. 1 may include many layers, including a dielectric layer 102 and traces 104, 106, and 112 in the dielectric layer 102. In the illustrated example, conductive vias 110 connect the traces 112 with conductive contacts located over the dielectric layer 102. The traces may be differential traces or single-ended traces. In the example illustrated in FIG. 1, the traces 106 are a pair of differential traces. The traces 104, 106, and 112 may include a conductive material such as a metal (e.g., copper (Cu), silver (Ag), gold (Au), aluminum (Al), or other metal).

The dielectric layer 102 may be a bottom-most layer on a base substrate, a top-most layer (e.g., the top-most layer under conductive contacts such as pads or other contacts), or an intermediate layer of the package. Although the dielectric layer 102 is shown as a single layer, the dielectric layer 102 may include one or more layers of a single dielectric material or multiple dielectric materials. For example, the dielectric layer 102 may include one or more layers of dielectric material under the conductive traces 104, 106, and 112, and one or more layers of dielectric material over the conductive traces 104, 106, and 112. In one example, the dielectric layer 102 includes one layer of a dielectric material under the conductive traces 104, 106, and 112, and one layer of the same dielectric material over the conductive traces 104, 106, and 112.

The dielectric layer 102 may include, for example, one or more of: a ceramic, an epoxy film (e.g., an epoxy resin) having filler particles therein, glass, an inorganic material, a build-up film (e.g., Ajinomoto Build-up Film (ABF)), or combinations of organic and inorganic materials. In one example, the dielectric layer 102 is formed from a composite material, such as an epoxy with a filler material 103A, 103B. In one such example, the filler material 103A, 103B is included in the epoxy to lower the CTE of the epoxy (e.g., to match the CTE of silicon). In the illustrated example, two different sizes of filler material 103A (filler particles with a larger diameter) and 103B (filler particles with a smaller diameter) are depicted. However, a filler material with a single particle size may be included in the dielectric material. Similarly, a filler material with more than two sizes of filler particles may be included in the dielectric material. The filler material may include one or more of: SiO₂ (silicon dioxide or silica), silicon carbide, titanium nitride, aluminum nitride, porous silica, or other filler materials.

In the illustrated example, the traces 106 and the fillers 103A, 103B are coated with materials that have opposing surface chemistries (e.g., one hydrophobic and one hydrophilic). In one example, the fillers 103A, 103B are coated with a hydrophobic material and the traces 106 are coated with a hydrophilic material. In another example, the fillers 103A, 103B are coated with a hydrophilic material and the traces 106 are coated with a hydrophobic material. Although FIG. 1 shows both the traces 106 and the fillers 103A, 103B with coatings, in other examples, only the traces or only the fillers are coated. For example, the layer of dielectric material 102 may include a filler that is hydrophobic even without the coating (e.g., uncoated silica). In one such example, the traces are treated with a hydrophilic coating to cause the traces to have opposing surface chemistry relative to the filler.

The coating on the traces 106 may be, for example, a solid-state film, a thin film, a self-assembled monolayer (SAM), and a polymer. The coating material on the traces 106 may be, for example, a fluoropolymer, amine terminated alkyl chain polymer chain, CF₃, CF₄ terminated alkyl chain polymer, methyl terminated alkyl chain polymer and thiolate versions of all the aforementioned materials (e.g., fluoropolymer thiolate, etc.) and solid-state materials such as metal nitride, metal carbide, metal oxide, or other suitable coating materials. For example, for a solid-state coating, the material may be, but is not limited to, a metal oxide or a metal nitride. In the polymer case, the material may be, but is not limited to, a carbonaceous species or organic small molecule. FIG. 1 illustrates two examples of a coating on the traces 106: example 114 shows a SAM or film of CF₃ (where thiol is the terminated end of the SAM, the other end is the CF₃), and example 116 shows a film of TiOx.

The coating on the filler may be, for example, a hydroxy (—OH), a carboxylate (—COO), titanium oxide, titanium nitride, titanium carbide, a metal oxide such as aluminum oxide or other metal oxide, Alₙ(OH)ₘ, a metal nitride, a metal carbide, —CH₂—CH₂—, NH₃, CH₃, CF₃ or other suitable coating material. Thus, in one example, the filler coating can be a wettable species such as —OH, —COO—, aluminum oxide, or a hydrophobic species such as CH₃ or CF₃. FIG. 1 illustrates an example of coating on the traces: example 118 shows a coating of NH₃. Other coating materials are possible to cause the traces and the fillers to have opposing surface chemistry. It should be noted that the wettable species can be bonded to the filler using a siloxane or other covalent bond.

By coating the fillers 103A, 103B, the traces 106, or both the fillers and traces with materials so that the fillers and traces have opposing surface chemistry, a low-filler or filler-depleted region 101 can be formed via self-assembly. Self-assembly refers to the formation of a feature or pattern via a process in which the components (e.g., molecules) re-organize themselves from an initial structure to a new structure as described in the embodiments; the driving force for this self-assembly is entropy initiated by different surface chemistries (e.g., hydrophobic and hydrophilic surfaces). For example, when the fillers and/or traces are coated to have opposing surface chemistries, the fillers move away (e.g., diffuse) from the traces in the dielectric material to form a void or low-filler patch in the dielectric material.

In one example, the filler-depleted area 101 has a radial, non-linear shape. In the example of FIG. 1, the filler-depleted area 101 is formed around a pair of differential traces, causing the area 101 to have the shape of two adjacent ovoid-shaped areas 101A and 101B. Although the area 101 is shown as two adjacent ovoids, the filler-depleted area 101 may have other radial shapes such a single ovoid (e.g., around a single trace), spherical (e.g., around a single trace), or two adjacent spheres (e.g., around a pair of traces). Regardless of the specific radial shape of the filler-depleted area, the lower filler content results in a resin-rich area with a lower dielectric constant around the traces to reduce capacitance build-up between traces and improve electrical performance of the package.

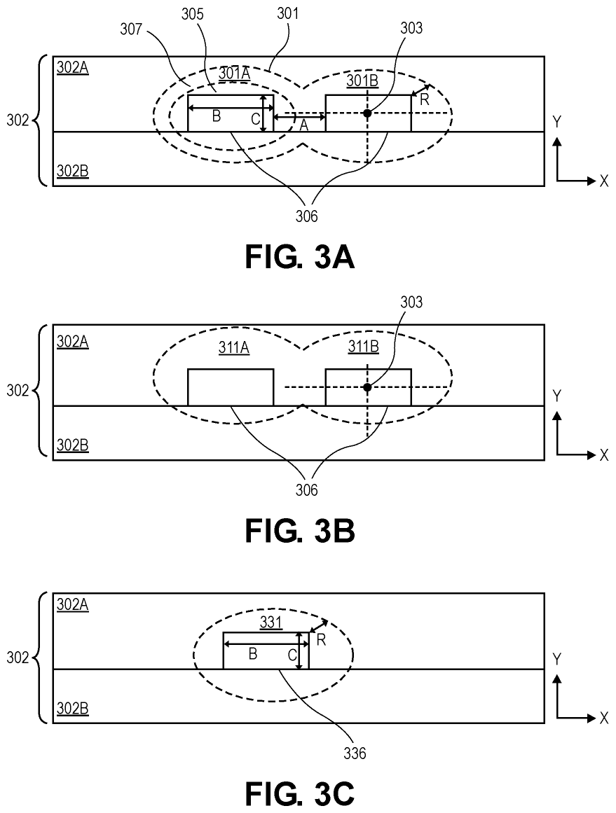

FIG. 2 is a graph illustrating an example of the dielectric constant as a function of frequency within and external to a filler-depleted region of a dielectric material. The line 202 represents the dielectric constant of a dielectric material (e.g., the material of layer 102 of FIG. 1) in areas other than the filler-depleted region (e.g., a relatively a resin-poor area in the case of an epoxy resin with a high filler content). The line 204 represents the dielectric constant of the same dielectric material in a filler-depleted region (e.g., a resin-rich area in the case of an epoxy resin, such as the region 101 of FIG. 1). The dielectric constant of the dielectric material outside of the filler-depleted area (line 202) is higher than the dielectric constant of the dielectric material in the filler-depleted area (line 204). The difference in dielectric constant becomes more pronounced at higher frequencies. Therefore, the filler-depleted area can be particularly beneficial for traces that are to be operated at high frequencies, such as typical differential traces.

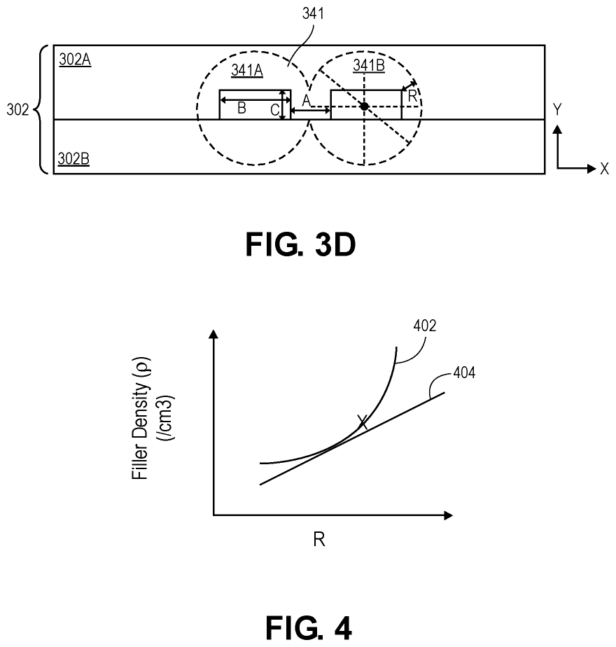

FIGS. 3A-3D illustrate examples of cross-sections of filler-depleted areas in a dielectric material. The cross-sections of FIGS. 3A-3D are along the xy-plane through the z-axis, where the z-axis is shown as going into the page. In these examples, the y-axis represents the direction in which the layers are formed over the substrate along the xz-plane. For example, the dielectric layer 302 is formed as a layer in the xz-plane with a thickness along the y-axis. Similarly, the traces 306 have a thickness C along the y-axis, a width B along the x-axis, and a length (not shown) along the z-axis. In one example, the traces 306 have a width B of 2-100 um and a thickness C in a range of 5-40 um. The traces 306 are separated by a distance A along the x-axis. In one example, the distance between the adjacent traces 306 is in the range of 1-50 um.

FIG. 3A illustrates a filler-depleted area 301 of the dielectric material 302 around a pair of traces 306. In one example, the filler-depleted area provides a low dielectric constant area around the traces 306. In this example, the filler-depleted region 301 is formed by two adjacent radial regions 301A and 301B around the pair of traces 306. The filler-depleted radial region 301 has a lower volume-percentage of filler than other regions of the layer of dielectric material 302 external to the filler-depleted region 301. Thus, in one example, the filler-depleted region has a lower dielectric constant than other regions of the layer of dielectric material external to the filler-depleted region. In one example, the volume-percentage of filler in the radial region is in a range of 0%-50%, and the volume-percentage of filler the other regions of the layer of dielectric material external to the radial region are in a range of 25%-95%.

In one example, the filler-depleted areas 301A and 301B include a central region 305 closest to the traces 306 that is void of filler. In one example, there is a gradient of filler increasing in volume-percentage from the central region 305 to an outer boundary of the radial regions 301A and 301B, where the outer boundary is depicted by the outer dotted-line of the regions 301A and 301B. Thus, in one example, there is a void of filler in the central region 305 that is adjacent to the traces 306, and an outer region 307 has a gradient of filler increasing in the direction from the central region to the outer boundary.

Due to the gradient of filler, there are typically no visible or linear seams between the filler-depleted region 301 and other regions of the dielectric layer 302 external to the region 301. However, the outer boundary of a radial region such as the regions 301A and 301B can be defined as the location where the

$$\frac{{d}^{2} ρ}{{dR}^{2}} = 0 ,$$

where

$$\frac{d ρ}{dR}$$

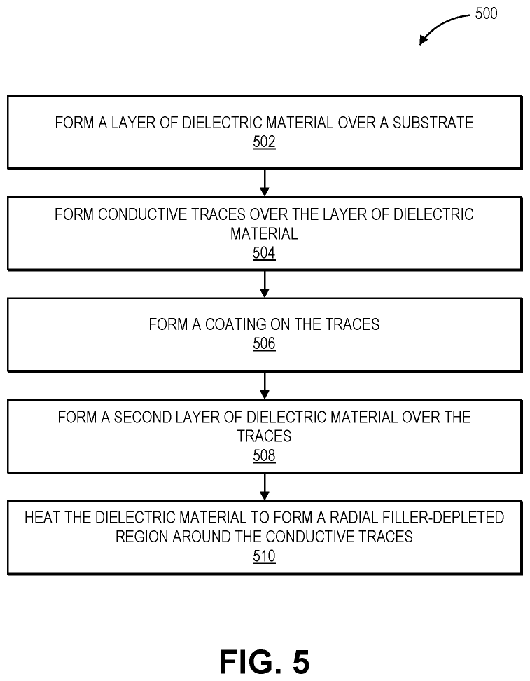

is maximum, where ρ is the tiller density and R is the distance from the trace in any given direction, assuming the filler density as a function of R is non-linear. In an example in which the filler density as a function of R is linear, then the boundary may be defined as the point at which ρ(R) is 50% of the origin value or R=0. FIG. 4 is a graph illustrating an example of filler density as a function of distance from the traces for both a non-linear case (line 402) and a linear case (line 404). In FIG. 4, an X shows approximately where the boundary of the filler-depleted region may be defined for a non-linear case.

Referring again to FIG. 3A, the illustrated example shows two ovoid-shaped areas around a pair of traces 306, which is depicted as two ovals in the cross-sectional view. In this example, the dielectric layer 302 is formed from two layers 302A and 302B of the same material. Because the traces 306 are surrounded by the same dielectric material, the filler is likely to diffuse at a similar or same rate in all directions, resulting in filler-depleted regions with radial symmetry about the xz-plane, the-yz plane, and the xy-plane at the center point 303 of each of the traces 306. Therefore, the filler-depleted regions 301A and 301B are symmetrical about the center of the traces, as shown by the dotted lines along the x-axis and y-axis through the center 303 of one of the traces 306. In one example in which the filler-depleted regions are ovoid, the radial symmetry of the filler-depleted regions is C2 radial symmetry along the long and short axis of the oval.

Other examples of filler-depleted areas may lack symmetry about the center of the traces along one or more planes. For example, FIG. 3B illustrates another example of a layer of dielectric material 302 including ovoid-shaped filler-depleted regions 311A and 311B. In this example, the layers 302A and 302B of dielectric material below and over the conductive traces 306 include different dielectric materials. The filler may diffuse differently in the different dielectric materials 302A and 302B. Therefore, the example in FIG. 3B shows a package in which the filler-depleted areas 311A and 311B are asymmetric about the xz-plane (e.g., the cross-section shown in FIG. 3B is asymmetric about the x-axis at the center point 303 of one of the traces 306.

Although the previous examples depict pairs of traces, a filler-depleted region may also be formed around a single trace. For example, FIG. 3C illustrates an example of a single trace 336 surrounded by a radial region 331. In this example, the radial region 331 is in the shape of a single ovoid or sphere rather than multiple adjacent and overlapping ovoids or spheres as illustrated in FIGS. 3A and 3B.

FIG. 3D illustrates another example of a cross-section of a filler-depleted area in a dielectric material. The example in FIG. 3D illustrates a filler-depleted region 341 having the shape of two adjacent spheres, as shown by the circular regions 341A and 341B.

Regardless of the specific radial shape, the filler-depleted region surrounds the traces and allows for modulation of the characteristics (e.g., electrical, thermal, or other characteristics) of the material in that region without impacting the surrounding dielectric material and without requiring a patch of an additional different dielectric material around the traces. The radial region may have the shape of one or more spheres, one or more ovoids, or other radial shape.

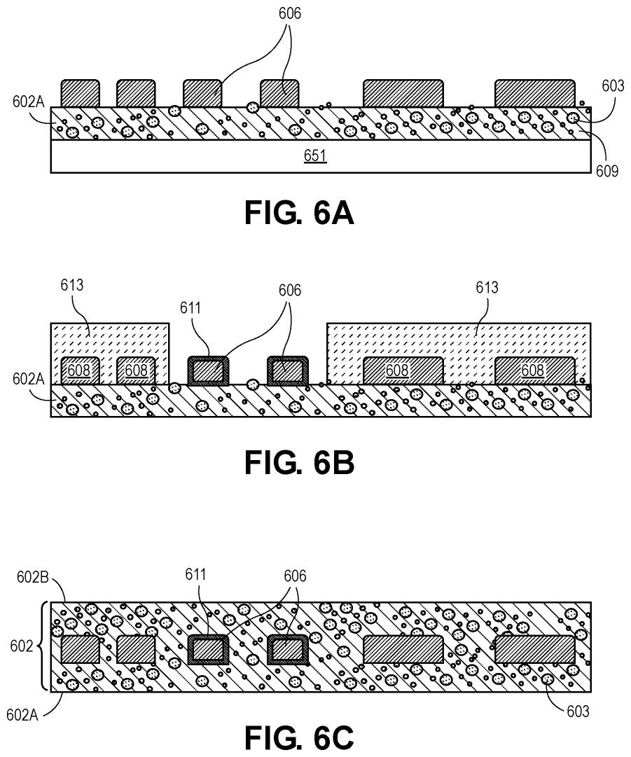

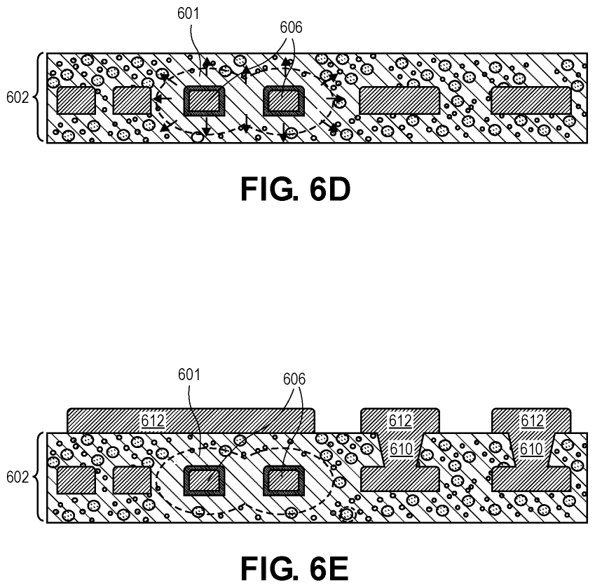

FIG. 5 is a flow diagram of an example of a process for the manufacture of a package with a dielectric layer having a low-filler region. FIGS. 6A-6E illustrate cross-sectional views of various stages corresponding to the process of FIG. 5, according to one example.

In one example, a method of manufacture of a package involves forming a plurality of conductive traces in a layer of dielectric material, where the dielectric material includes a filler material that has opposing surface chemistry relative to the plurality of conductive traces. Heat is then applied to the layer of dielectric material to form a filler-depleted radial region of the dielectric material around each of the plurality of conductive traces.

Referring first to FIG. 5, the method 500 involves forming a layer of dielectric material over a substrate, at block 502. For example, referring to FIG. 6A, the method may involve forming a first dielectric layer 602A over a substrate 651. The substrate may include, for example, layers of dielectric material and conductive material, with lines of conductive material in one layer electrically coupled to lines of conductive material in an adjacent layer by vias of the conductive material. In one example, the substrate 651 is formed using printed circuit board (PCB) fabrication techniques. The layer of dielectric material 602A may be any suitable dielectric material for use in a package; the dielectric material 602A may be the same as, or similar to, the layer of dielectric material 102 discussed above. For example, the layer of dielectric material 602A may include an epoxy 609 with filler particles 603. In one example, the filler particles 603 are uniformly distributed within the epoxy 609. In one example, the filler 603 includes coated filler particles, such as described above with respect to FIG. 1. The filler particles may be coated according to any coating process. For example, the filler particles may be submerged in a bath having ligand for forming the coating. In other examples, the filler is non-coated.

Referring again to FIG. 5, the method 500 involves forming conductive traces over the layer of dielectric material, at block 504. For example, referring to FIG. 6A, the method involves forming conductive traces 606 on the layer of dielectric material 602A. The conductive traces may be the same or similar to the conductive traces 106 of FIG. 1.

Referring again to FIG. 5, after forming the conductive contacts, the method 500 involves forming a coating on the traces, at block 506. Forming a coating on the traces may involve a lithographic process. For example, referring to FIG. 6B, a photoresist 613 such as a dry film photoresist (DFR) or other suitable material is deposited over the traces 606 and any other exposed surfaces of the substrate such as traces 608 and exposed portions of the layer of dielectric material 602A. The photoresist is then removed (e.g., etched) in the area over and around the traces 606. After exposing the traces 606, the coating 611 may be formed or deposited on the traces 606. Coating the traces may involve, for example, depositing a self-assembled monolayer or a solid-state film on the traces. In other examples, the traces may not be coated.

Referring again to FIG. 5, after coating the traces, a second layer of dielectric material is formed over the traces, at block 508. Forming the second dielectric layer may involve, for example, lamination and encapsulation of a build-up film with shell fillers. For example, referring to FIG. 6C, the second layer 602B of dielectric material is formed over the conductive traces 606. The filler 603 is evenly distributed throughout the dielectric layer 602.

Referring again to FIG. 5, the method 500 then involves heating the dielectric material to form a radial filler-depleted region around the conductive traces, at block 510. For example, referring to FIG. 6D, the method involves a thermal step to instigate phase segregation in the dielectric layer 602. Heat applied to the dielectric material causes the filler particles to move away from the traces to form a void around the traces 606. Thus, in one example, the applied heat and the difference in surface energy between the traces and the filler drives self-assembly of a filler-depleted zone 601 around the traces 606. After formation of the filler-depleted area 601, the subsequent processing operations may be performed to complete the package. For example, referring to FIG. 6E, additional etching and deposition may be performed to form conductive vias 610 and subsequent metal layers (e.g., conductive contacts 612).

Thus, the techniques described herein enable formation of a tunable dielectric material to allow for more flexibility in package design. A region having different properties, such as dielectric constant, may be formed via self-assembly in a dielectric layer by coating the traces and/or filler in the dielectric layer to have opposing surface chemistry. In one example, a filler-depleted region within the build-up film enables lowering the dielectric constant around the traces of interest while not affecting other material properties, such as thermomechanical properties such as CTE and modulus.

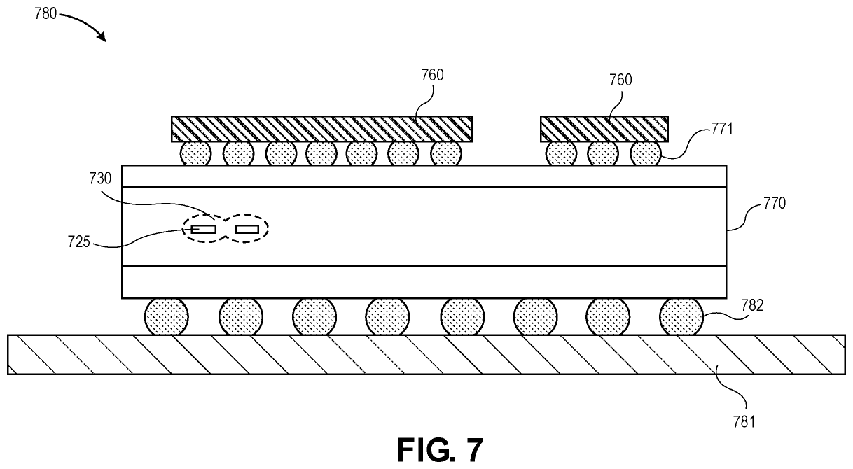

FIG. 7 is a cross-sectional illustration of an example of an electronic assembly 780 including a filler-depleted region. In one example, the microelectronic assembly 780 includes a board 781, such as a printed circuit board (PCB). In one example, one or more package substrates 770 may be electrically coupled with the board 781 by interconnects 782. For example, the interconnects 782 may include bumps, wire bonds, sockets, or any other suitable interconnect. In one example, one or more dies 760 may be electrically coupled with the package substrate 770 by interconnects 771.

In one example, the package substrate 770 includes a plurality of buildup layers and metal layers. In one example, the buildup layers include a dielectric material. In one example, traces 725 are embedded in the package substrate 770, such as in the dielectric build-up layers. The traces 725 may be surrounded by a filler-depleted area 730, such as the filler-depleted radial areas discussed herein.

In one example, the electronic assembly 780 is part of a computing system, such as a server system or other computing system. In one example, the filler-depleted area 730 around the traces 725 enable low loss, high-speed signaling. For example, the traces 725 include a width that reduces conductor losses, and the filler-depleted area 730 provides a lower dielectric constant that allows for impedance matching without needing to alter the dielectric thickness. Accordingly, high performance electronic systems with manufacturable process flows are provided in accordance with examples disclosed herein.

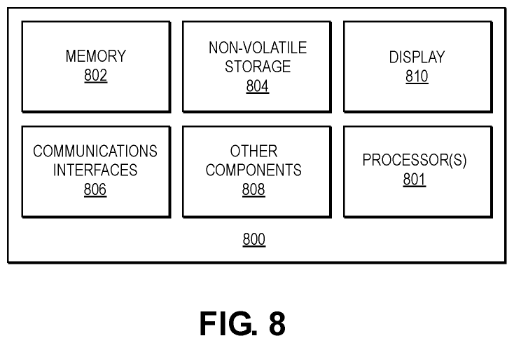

FIG. 8 provides an exemplary depiction of a computing system 800 (e.g., a smartphone, a tablet computer, a laptop computer, a desktop computer, a server computer, etc.). As observed in FIG. 8, the system 800 may include one or more processors or processing units 801. The processor(s) 801 may include one or more central processing units (CPUs), each of which may include, e.g., a plurality of general-purpose processing cores. The processor(s) 801 may also or alternatively include one or more graphics processing units (GPUs) or other processing units. The processor(s) 801 may include memory management logic (e.g., a memory controller) and I/O control logic.

The system 800 also includes memory 802 (e.g., system memory), non-volatile storage 804, communications interfaces 806, a display 810 (e.g., touchscreen, flat-panel), and other components 808. The other components may include, for example, a power supply (e.g., a battery or/or other power supply), sensors, power management logic, or other components. The communications interfaces 806 may include logic and/or features to support a communication interface. For these examples, communications interface 806 may include one or more communication interfaces that operate according to various communication protocols or standards to communicate over direct or network communication links or channels. Direct communications may occur via use of communication protocols or standards described in one or more industry standards (including progenies and variants) such as those associated with the PCIe specification. Network communications may occur via use of communication protocols or standards such those described in one or more Ethernet standards promulgated by IEEE. For example, one such Ethernet standard may include IEEE 802.3. Network communication may also occur according to one or more OpenFlow specifications such as the OpenFlow Switch Specification. Other examples of communications interfaces include, for example, a local wired point-to-point link (e.g., USB) interface, a wireless local area network (e.g., WiFi) interface, a wireless point-to-point link (e.g., Bluetooth) interface, a Global Positioning System interface, and/or other interfaces.

The computing system also includes non-volatile storage 804, which may be the mass storage component of the system. A non-volatile memory (NVM) device is a type of memory whose state is determinate even if power is interrupted to the device. In one embodiment, the NVM device may include block or byte-addressable, write-in-place memories. Examples may include, but are not limited to, single or multi-level Phase Change Memory (PCM) or phase change memory with a switch (PCMS), non-volatile types of memory that include chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other types of block or byte-addressable, write-in-place memory. In one example, the non-volatile storage 804 may include mass storage that is composed of one or more SSDs (solid state drives), DIMMs (dual in line memory modules), or other module or drive.

Examples of packages and assemblies with a dielectric layer including a self-assembled filler-depleted region, and a method of manufacturing such packages and assemblies, follow.

Example 1: A package including: a substrate, a layer of dielectric material over the substrate, the layer of dielectric material including a filler material, a plurality of conductive traces in the layer of dielectric material, and a filler-depleted radial region of the dielectric material around each of the plurality of conductive traces, wherein the filler-depleted radial region has a lower volume-percentage of filler than other regions of the layer of dielectric material.

Example 2: The package of example 1, wherein: the plurality of conductive traces includes a coating with opposing surface chemistry relative to the filler material.

Example 3: The package of any of examples 1-2, wherein: the filler material includes a coating with opposing surface chemistry relative to the plurality of conductive traces.

Example 4: The package of any of examples 1-3, wherein: the plurality of conductive traces includes a coating of a hydrophilic material, and the filler material includes a coating of a hydrophobic material.

Example 5: The package of any of examples 1-3, wherein: the plurality of conductive traces includes a coating of a hydrophobic material, and the filler material includes a coating of a hydrophilic material.

Example 6: The package of any of examples 1-5, wherein: the filler-depleted radial region around a conductive trace of the plurality of conductive traces has radial symmetry about a center point of the conductive trace.

Example 7: The package of any of examples 1-6, wherein: the radial region includes a spherical shape.

Example 8: The package of any of examples 1-6, wherein: the radial region includes an ovoid shape.

Example 9: The package of any of examples 1-8, wherein: the radial region includes a central region void of filler, and an outer region with a gradient of filler increasing in volume-percentage from the central region to an outer boundary of the radial region.

Example 10: The package of any of examples 1-9, wherein: the volume-percentage of filler in the radial region is in a range of 0%-50%, and the volume-percentage of filler the other regions of the layer of dielectric material external to the radial region are in a range of 25%-95%.

Example 11: The package of any of examples 1-10, wherein: the plurality of conductive traces include pairs of differential traces.

Example 12: The package of any of examples 1-11, wherein: the plurality of conductive traces include single-ended traces.

Example 13: The package of any of examples 1-12, wherein: a coating on the plurality of conductive traces includes one or more of: a solid-state film, a thin-film, a self-assembled monolayer, and a polymer.

Example 14: The package of any of examples 1-13, wherein: a coating on the plurality of conductive traces includes one or more of fluoropolymer, amine terminated alkyl chain polymer chain, CF4 terminated alkyl chain polymer, methyl terminated alkyl chain polymer, metal nitride, metal carbide, metal oxide, and an organic material.

Example 15: The package of any of examples 1-14, wherein: a coating on the filler material includes one or more of: a hydroxy (—OH), a carboxylate (—COO), titanium oxide, titanium nitride, titanium carbide, a metal oxide such as aluminum oxide or other metal oxide, a metal nitride, a metal carbide, CH3, and CF3.

Example 16: The package of any of examples 1-15, further including an integrated circuit electrically coupled with the plurality of conductive traces.

Example 17: A microelectronic assembly including: a substrate, a layer of dielectric material over the substrate, the layer of dielectric material including a hydrophobic filler material, a plurality of conductive traces in the layer of dielectric material, an integrated circuit over the substrate and electrically coupled with the plurality of conductive traces, a coating of a hydrophilic material on the plurality of conductive traces, and a radial region around each of the plurality of conductive traces with a lower volume-percentage of the hydrophobic filler material than other regions of the layer of dielectric material external to the radial region.

Example 18: The microelectronic assembly of example 17, wherein the layer of dielectric material is in accordance with any of examples 1-15.

Example 19: A method including: forming a plurality of conductive traces in a layer of dielectric material, wherein the dielectric material includes a filler material that has opposing surface chemistry relative to the plurality of conductive traces, and applying heat to the layer of dielectric material to form a filler-depleted radial region of the dielectric material around each of the plurality of conductive traces.

Example 20: The method of example 19, further including coating the plurality of conductive traces (e.g., with a hydrophilic material), coating the filler (e.g., with a hydrophobic material), or coating both the plurality of traces and the filler.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A package comprising:
a substrate;
a layer of dielectric material over the substrate, the layer of dielectric material including a filler material;
a plurality of conductive traces in the layer of dielectric material; and
a filler-depleted radial region of the dielectric material around each of the plurality of conductive traces, wherein the filler-depleted radial region has a lower volume-percentage of filler than other regions of the layer of dielectric material.

2. The package of claim 1, wherein:
the plurality of conductive traces includes a coating with opposing surface chemistry relative to the filler material.

3. The package of claim 1, wherein:
the filler material includes a coating with opposing surface chemistry relative to the plurality of conductive traces.

4. The package of claim 1, wherein:
the plurality of conductive traces includes a coating of a hydrophilic material; and
the filler material includes a coating of a hydrophobic material.

5. The package of claim 1, wherein:
the plurality of conductive traces includes a coating of a hydrophobic material; and
the filler material includes a coating of a hydrophilic material.

6. The package of claim 1, wherein:
The filler-depleted radial region around a conductive trace of the plurality of conductive traces has radial symmetry about a center point of the conductive trace.

7. The package of claim 1, wherein:
the radial region includes a spherical shape.

8. The package of claim 1, wherein:
the radial region includes an ovoid shape.

9. The package of claim 1, wherein:
the radial region includes a central region void of filler, and an outer region with a gradient of filler increasing in volume-percentage from the central region to an outer boundary of the radial region.

10. The package of claim 1, wherein:
the volume-percentage of filler in the radial region is in a range of 0%-50%, and the volume-percentage of filler the other regions of the layer of dielectric material external to the radial region are in a range of 25%-95%.

11. The package of claim 1, wherein:
the plurality of conductive traces include pairs of differential traces.

12. The package of claim 1, wherein:
the plurality of conductive traces include single-ended traces.

13. The package of claim 2, wherein:
the coating on the plurality of conductive traces includes one or more of: a solid-state film, a thin-film, a self-assembled monolayer, and a polymer.

14. The package of claim 13, wherein:
the coating on the plurality of conductive traces includes one or more of fluoropolymer, amine terminated alkyl chain polymer chain, CF₄ terminated alkyl chain polymer, methyl terminated alkyl chain polymer, metal nitride, metal carbide, metal oxide, and an organic material.

15. The package of claim 3, wherein:
the coating on the filler material includes one or more of: a hydroxy (—OH), a carboxylate (—COO), titanium oxide, titanium nitride, titanium carbide, a metal oxide such as aluminum oxide or other metal oxide, a metal nitride, a metal carbide, CH₃, and CF₃.

16. The package of claim 1, further comprising:
an integrated circuit electrically coupled with the plurality of conductive traces.

17. A microelectronic assembly comprising:
a substrate;
a layer of dielectric material over the substrate, the layer of dielectric material including a hydrophobic filler material;
a plurality of conductive traces in the layer of dielectric material;
an integrated circuit over the substrate and electrically coupled with the plurality of conductive traces;
a coating of a hydrophilic material on the plurality of conductive traces; and
a radial region around each of the plurality of conductive traces with a lower volume-percentage of the hydrophobic filler material than other regions of the layer of dielectric material external to the radial region.

18. The microelectronic assembly of claim 17, wherein:
the filler material includes a coating of a hydrophobic material.

19. A method comprising:
forming a plurality of conductive traces in a layer of dielectric material, wherein the dielectric material includes a filler material that has opposing surface chemistry relative to the plurality of conductive traces; and
applying heat to the layer of dielectric material to form a filler-depleted radial region of the dielectric material around each of the plurality of conductive traces.

20. The method of claim 19, further comprising:
coating the plurality of conductive traces with a hydrophilic material.

21. The method of claim 19, wherein:
the filler material includes a coating of a hydrophobic material.
